(19) United States
(12) Patent Application Publication
(10) Pub. No.: US 2018/0063903 A1
(43) Pub. Date: Mar. 1, 2018

(54) LIGHT-EMITTING DEVICE AND ILLUMINATING APPARATUS

(71) Applicant: Panasonic Intellectual Property Management Co., Ltd., Osaka (JP)

(72) Inventors: Yuya YAMAMOTO, Osaka (JP); Toshifumi OGATA, Osaka (JP); Shigeru IDO, Osaka (JP); Shun KUSUDA, Osaka (JP)

(73) Assignee: Panasonic Intellectual Property Management Co., Ltd., Osaka (JP)

(21) Appl. No.: 15/671,242

(22) Filed: Aug. 8, 2017

(30) Foreign Application Priority Data
Aug. 23, 2016 (JP) 2016-163165

(51) Int. Cl. H05B 33/08; F21S 8/02; F21V 23/00; F21V 23/06; F21V 29/89; H01L 33/50

(52) U.S. Cl. CPC H05B 33/083; F21S 8/02; F21V 23/005; F21K 9/20; F21V 29/89; H01L 33/508; F21V 23/06

(57) ABSTRACT

A light-emitting device includes a light emission controller which causes first and second light-emitting element groups to emit light, by supplying undulating voltage to the first and second light-emitting element groups. The light emission controller supplies the undulating voltage to the first light-emitting element group during a first period in which a magnitude of the undulating voltage is greater than a first predetermined value and at most a second predetermined value. The second predetermined value is less than a maximum value of the undulating voltage. The light emission controller supplies the undulating voltage to the first and second light-emitting element groups during a second period in which the magnitude of the undulating voltage is greater than the second predetermined value. The second light-emitting element group surrounds the first light-emitting element group.

### CROSS REFERENCE TO RELATED APPLICATION

This application claims the benefit of priority of Japanese Patent Application Number 2016-163165 filed on Aug. 23, 2016, the entire content of which is hereby incorporated by reference.

### BACKGROUND

### 1. Technical Field

The present disclosure relates to a light-emitting device and an illuminating apparatus including the light-emitting device.

### 2. Description of the Related Art

Conventionally, light-emitting modules (light-emitting devices) have been known which include light-emitting diodes (LEDs) mounted on boards. Patent Literature (PTL) 1 (Japanese Unexamined Patent Application Publication No. 2009-218192) discloses a light-emitting module having a satisfactory distribution of light emitted by light-emitting elements.

### SUMMARY

A light-emitting device is known which operates by being supplied with undulating voltage (ripple voltage). When a voltage value of the supplied undulating voltage increases, such a light-emitting device performs light emission control for increasing the number of LEDs emitting light. The light-emitting device flickers, because the number of LEDs emitting light varies depending on time.

The present disclosure provides a light-emitting device and an illuminating apparatus which are capable of reducing a flicker.

A light-emitting device according to one aspect of the present disclosure includes: a board; a first light-emitting element group and a second light-emitting element group which are disposed on the board, each of the first light-emitting element group and the second light-emitting element group including at least one light-emitting element; and a light emission controller which causes the first light-emitting element group and the second light-emitting element group to emit light, by supplying undulating voltage to the first light-emitting element group and the second light-emitting element group, wherein the light emission controller: causes, from among the first light-emitting element group and the second light-emitting element group, the first light-emitting element group to emit light, by supplying the undulating voltage to the first light-emitting element group, during a first period in which a magnitude of the undulating voltage is greater than a first predetermined value and at most a second predetermined value, the second predetermined value being less than a maximum value of the undulating voltage; and causes the first light-emitting element group and the second light-emitting element group to emit light, by supplying the undulating voltage to the first light-emitting element group and the second light-emitting element group, during a second period in which the magnitude of the undulating voltage is greater than the second predetermined value, and the second light-emitting element group surrounds the first light-emitting element group on the board.

An illuminating apparatus according to one aspect of the present disclosure includes: the light-emitting device; and a lens disposed opposite the light-emitting device.

A light-emitting device and an illuminating apparatus according to one aspect of the present disclosure are capable of reducing a flicker.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is an external perspective view illustrating a light-emitting device according to Embodiment 1;

FIG. 2 is a plan view illustrating the light-emitting device according to Embodiment 1;

FIG. 3 is a plan view illustrating the internal structure of the light-emitting device according to Embodiment 1;

FIG. 4 is a schematic cross-sectional view illustrating the light-emitting device along line IV-IV in FIG. 2;

FIG. 5 is a diagram illustrating the configuration of a light emission control circuit;

FIG. 6 is a graph illustrating a waveform of undulating voltage to describe operations performed by the light-emitting device according to Embodiment 1;

FIG. 7 is a diagram illustrating an electrical connection relationship among LED chips according to a variation;

FIG. 8 is an exploded perspective view illustrating an illuminating apparatus according to Embodiment 2; and

FIG. 9 is a schematic cross-sectional view illustrating the illuminating apparatus according to Embodiment 2.

### DETAILED DESCRIPTION OF THE EMBODIMENTS

Hereinafter, a light-emitting device etc. according to an embodiment will be described with reference to the drawings. It is to be noted that each of embodiments described below represents a generic or specific example. The numerical values, shapes, materials, structural elements, the arrangement and connection of the structural elements, etc. shown in the following embodiments are mere examples, and are not intended to limit the scope of the present disclosure. Furthermore, among the structural elements in the following embodiments, structural elements not recited in any one of the independent claims which indicates the broadest concept are described as optional structural elements.

It is to be noted that the figures are schematic diagrams and are not necessarily precise illustrations. Furthermore, in the figures, substantially same structural elements are assigned the same reference signs, and overlapping description may be omitted or simplified.

### Embodiment 1

### [Configuration of Light-Emitting Device]

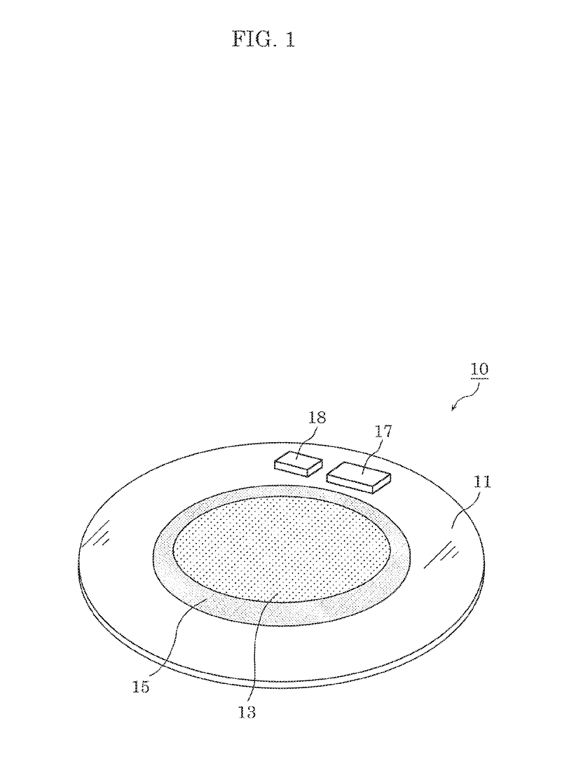

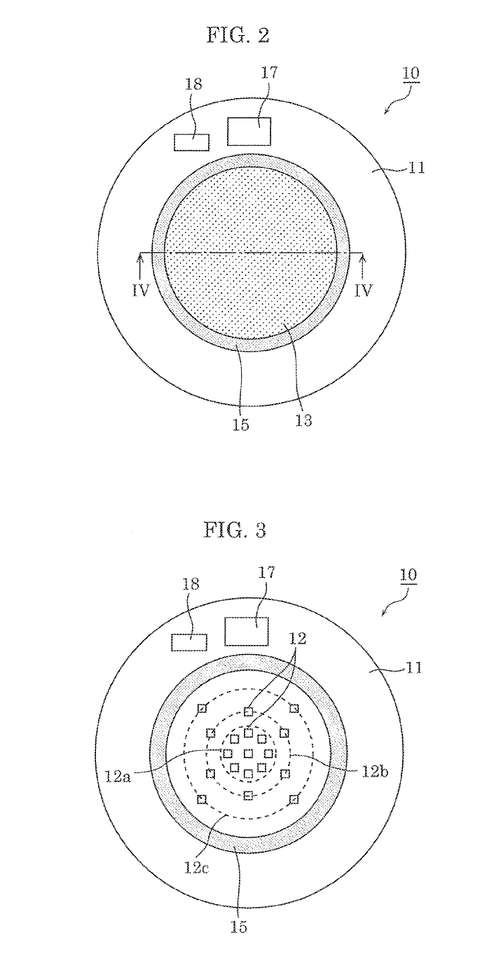

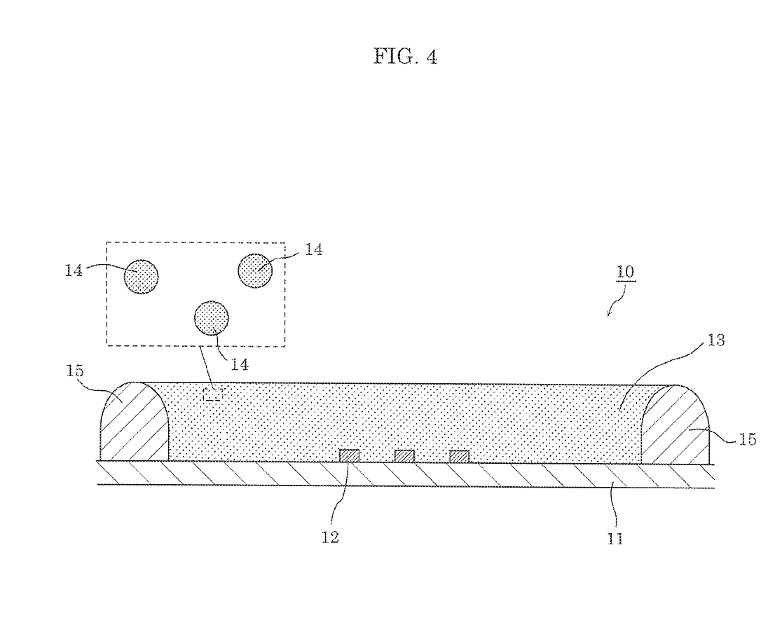

First, the configuration of a light-emitting device according to Embodiment 1 will be described with reference to the drawings. FIG. 1 is an external perspective view illustrating the light-emitting device according to Embodiment 1. FIG. 2 is a plan view illustrating the light-emitting device according to Embodiment 1. FIG. 3 is a plan view illustrating the internal structure of the light-emitting device according to Embodiment 1. FIG. 4 is a schematic cross-sectional view illustrating the light-emitting device along line IV-IV in FIG. 2. It is to be noted that FIG. 3 is a plan view in which sealing member 13 is removed in FIG. 2 to show an arrangement of LED chips 12.

As illustrated in FIG. 1 to FIG. 4, light-emitting device 10 according to Embodiment 1 includes board 11, LED chips 12, sealing member 13, and dam member 15. In addition, light-emitting device 10 includes a light emission control circuit which causes LED chips 12 to emit light, and the light emission control circuit includes full-wave rectifying circuit 17 and controller 18.

Light-emitting device 10 is an LED module having a so-called chip on board (COB) structure in which LED chips 12 are directly mounted on board 11. In light-emitting device 10, full-wave rectifying circuit 17 full-wave rectifies alternating-current voltage supplied by an external power source outside light-emitting device 10, and converts the alternating-current voltage into undulating voltage. LED chips 12 are supplied (applied) with the undulating voltage. In other words, LED chips 12 included in light-emitting device 10 emit light by pulsating current flowing therethrough.

It is to be noted that the external power source is, for example, an electric power system, and the alternating-current voltage supplied to light-emitting device 10 is, for example, sine wave alternating-current voltage having a frequency of 50 Hz or 60 Hz. Accordingly, the aforementioned undulating voltage has an alternating-current waveform (a waveform resulting from full-wave rectifying sine wave alternating-current voltage).

Board 11 is a mounting board on which LED chips 12, full-wave rectifying circuit 17, and controller 18 are mounted. It is to be noted that, though not shown in FIG. 1 to FIG. 4, wires etc. for electrically connecting LED chips 12 are mounted on board 11. Board 11 is, for example, a metal base board or a ceramic board. In addition, board 11 may be a resin board including resin as a base material.

Examples of a ceramic board include an alumina board comprising aluminum oxide (alumina) or an aluminum nitride board comprising aluminum nitride. Furthermore, examples of a metal base board include an aluminum alloy board, a ferroalloy board, or a copper alloy board on the surface of which an insulating film is formed. Examples of a resin board include a glass epoxy board comprising glass fiber and epoxy resin.

It is to be noted that examples of board 11 include a board having a high optical reflectance (e.g., an optical reflectance of at least 90%). By using the board having the high optical reflectance as board 11, light emitted by LED chips 12 can be reflected off the surface of board 11. As a result, light extraction efficiency of light-emitting device 10 is improved. Such a board is exemplified by a white ceramic board comprising, for example, alumina as a base material.

Moreover, examples of board 11 include a translucent board having a high light transmission rate. Such a board is exemplified by a translucent ceramic board comprising polycrystalline alumina or aluminum nitride, a transparent glass board comprising glass, a crystal board comprising crystal, a sapphire board comprising sapphire, or a transparent resin board comprising a transparent resin material.

It is to be noted that although board 11 is circular in Embodiment 1, board 11 may be of a different shape such as rectangular.

LED chips 12 are examples of a light-emitting element, and are blue LED chips which emit blue light. Examples of LED chips 12 include gallium nitride LED chips which are made from, for example, an InGaN material and whose central wavelength (peak wavelength in the spectrum of emitted light) is at least 430 nm and at most 470 nm.

As illustrated in FIG. 3, in light-emitting device 10, LED chips 12 are classified into first light-emitting element group 12a, second light-emitting element group 12b, and third light-emitting element group 12c.

First light-emitting element group 12a is disposed in an area including the center of light emission (the location of an optical axis) of light-emitting device 10, on board 11. First light-emitting element group 12a includes LED chips 12 surrounded by a broken line indicated by the reference sign of first light-emitting element group 12a.

The number of LED chips 12 included in first light-emitting element group 12a is not particularly limited. First light-emitting element group 12a may include at least one LED chip 12. In an example shown in FIG. 3, the number of LED chips 12 included in first light-emitting element group 12a is greater than both the number of LED chips 12 included in second light-emitting element group 12b and the number of LED chips 12 included in third light-emitting element group 12c. In other words, the greatest number is the number of LED chips 12 included in first light-emitting element group 12a located innermost among all the light-emitting element groups caused to emit light by the light emission control circuit.

Second light-emitting element group 12b is disposed circularly (annularly) to surround first light-emitting element group 12a on board 11. That is to say, second light-emitting element group 12b is disposed on a periphery of (around) first light-emitting element group 12a on board 11. Second light-emitting element group 12b includes LED chips 12 on a broken line indicated by the reference sign of second light-emitting element group 12b.

The number of LED chips 12 included in second light-emitting element group 12b is not particularly limited. In the example shown in FIG. 3, the number of LED chips 12 included in second light-emitting element group 12b is less than the number of LED chips included in first light-emitting element group 12a, and greater than the number of LED chips 12 included in third light-emitting element group 12c.

Third light-emitting element group 12c is disposed to surround second light-emitting element group 12b on board 11. That is to say, third light-emitting element group 12c is disposed on a periphery of (around) second light-emitting element group 12b on board 11. Third light-emitting element group 12c is disposed, for example, circularly (annularly) in a concentric fashion with second light-emitting element group 12b on board 11. Third light-emitting element group 12c includes LED chips 12 on a broken line indicated by the reference sign of third light-emitting element group 12c.

The number of LED chips 12 included in third light-emitting element group 12c is not particularly limited. In the example shown in FIG. 3, the number of LED chips 12 included in third light-emitting element group 12c is less than both the number of LED chips 12 included in first light-emitting element group 12a and the number of LED chips 12 included in second light-emitting element group 12b.

First light-emitting element group 12a, second light-emitting element group 12b, and third light-emitting element group 12c mutually differ in light emission periods during which light-emitting device 10 operates. The operations performed by light-emitting device 10 will be described in detail later.

It is to be noted that bonding wires etc. may be used for the electrical connection of LED chips 12, in addition to the wires disposed on board 11. Examples of a metal material of the bonding wires and wires include gold (Au), silver (Ag), and copper (Cu).

Dam member 15 is disposed on board 11 and serves to block sealing member 13. For example, a thermosetting resin or a thermoplastic resin having an insulating property is used as dam member 15. More specifically, a silicone resin, a phenol resin, an epoxy resin, a bismaleimide triazine resin, a polyphthalamide (PPA) resin, or the like is used as dam member 15.

It is desirable that dam member 15 have a light-reflecting property so as to increase the light extraction efficiency of light-emitting device 10. Thus, a resin in a white color (what is called a white resin) is used as dam member 15. It is to be noted that dam member 15 may include particles of TiO₂, Al₂O₃, ZrO₂, MgO, and the like so as to increase the light-reflecting property of dam member 15.

In light-emitting device 10, dam member 15 is formed annularly to surround LED chips 12 (first light-emitting element group 12a, second light-emitting element group 12b, and third light-emitting element group 12c) from outside. Sealing member 13 is provided in the area surrounded by dam member 15. It is to be noted that the outer shape of dam member 15 may be formed of a rectangular annular shape.

Sealing member 13 includes yellow phosphor 14 (shown in FIG. 4) and seals LED chips 12. Specifically, sealing member 13 collectively seals first light-emitting element group 12a, second light-emitting element group 12b, and third light-emitting element group 12c. A base material of sealing member 13 is a translucent resin material. As the translucent resin material, for example, a methyl-based silicone resin is used, but an epoxy resin, a urea resin, or the like may be used.

Yellow phosphor 14 is one example of a phosphor (phosphor particles) and is excited by the light emitted by LEC chips 12 to emit yellow fluorescent light. For example, yttrium aluminum garnet (YAG)-based phosphor is used as yellow phosphor 14.

In this configuration, the wavelength of a portion of the blue light emitted by LED chips 12 is converted by yellow phosphor 14 included in sealing member 13, such that the portion is transformed into yellow light. Then, the blue light not absorbed by yellow phosphor 14 and the yellow light resulting from the wavelength conversion by yellow phosphor 14 are diffused and mixed inside sealing member 13. Consequently, sealing member 13 (light-emitting device 10) emits white light.

Full-wave rectifying circuit 17 is a diode bridge which generates undulating voltage by full-wave rectifying sine wave alternating-current voltage supplied by the external power source. Full-wave rectifying circuit 17 is included in the light emission control circuit of light-emitting device 10 and is disposed outside dam member 15 on board 11. Full-wave rectifying circuit 17 is not an essential structural element, and may be omitted accordingly.

Controller 18 performs light emission control (drive control) of LED chips 12 according to an alternating-current waveform of the generated undulating voltage. Controller 18 controls switch elements (to be described later) included in the light emission control circuit of light-emitting device 10, based on the magnitude of the undulating voltage. With this, the number of LED chips 12 emitting light is changed according to the magnitude of the undulating voltage. Controller 18 is included in the light emission control circuit of light-emitting device 10 and is disposed outside dam member 15 on board 11. Controller 18 is realized as an integrated circuit (IC), but may be realized as a processor, a microcomputer, or a dedicated communication circuit.

### [Configuration of Light Emission Control Circuit]

Next, the configuration of the light emission control circuit included in light-emitting device 10 will be described. FIG. 5 is a diagram illustrating the configuration of the light emission control circuit.

By supplying undulating voltage generated by rectifying alternating-current voltage to first light-emitting element group 12a and second light-emitting element group 12b, light emission control circuit 20 causes first light-emitting element group 12a and second light-emitting element group 12b to emit light. As illustrated in FIG. 5, light emission control circuit 20 specifically includes first switch element 16a, second switch element 16b, third switch element 16c, full-wave rectifying circuit 17, controller 18, and resistance element 19. First light-emitting element group 12a, second light-emitting element group 12b, third light-emitting element group 12c, and external power source 25 are not included in light emission control circuit 20. Light emission control circuit 20 is disposed on board 11. It is to be noted that light emission control circuit 20 may be disposed on a board different from board 11, and the board and board 11 may be electrically connected to each other via a connector or the like.

Controller 18 turns on (conduction, short-circuit) and off (nonconduction, open-circuit) first switch element 16a, second switch element 16b, and third switch element 16c. First switch element 16a is turned on to supply the undulating voltage to first light-emitting element group 12a. Second switch element 16b is turned on to supply the undulating voltage to second light-emitting element group 12b. Third switch element 16c is turned on to supply the undulating voltage to third light-emitting element group 12c.

Specifically, first switch element 16a, second switch element 16b, and third switch element 16c each are a semiconductor switch element such as a field effect transistor (FET), but may be a relay element or the like. First switch element 16a, second switch element 16b, and third switch element 16c are disposed on board 11.

Light emission control circuit 20 also includes wires or the like for electrically connecting first switch element 16a, second switch element 16b, third switch element 16c, full-wave rectifying circuit 17, and controller 18. Light emission control circuit 20 may include a resistance element and a capacitor as necessary.

For example, resistance element 19 is used to restrict current flowing through first light-emitting element group 12a, second light-emitting element group 12b, third light-emitting element group 12c to be less than or equal to a predetermined value. Light emission control circuit 20 may include, for example, a constant current circuit which causes current flowing through LED chips 12 (first light-emitting element group 12a, second light-emitting element group 12b, and third light-emitting element group 12c) to be an almost constant current value, instead of resistance element 19. It is to be noted that light emission control circuit 20 does not include a smoothing capacitor which smoothes undulating voltage.

First, the following describes an electrical connection relationship among LED chips 12 in each of first light-emitting element group 12a, second light-emitting element group 12b, and third light-emitting element group 12c.

LED chips 12 included in first light-emitting element group 12a are connected in series. Likewise, LED chips 12 included in second light-emitting element group 12b are connected in series, and LED chips 12 included in third light-emitting element group 12c are connected in series. First light-emitting element group 12a, second light-emitting element group 12b, and third light-emitting element group 12c are connected in series.

Next, the following describes an electrical connection relationship among light emission control circuit 20, first light-emitting element group 12a, second light-emitting element group 12b, and third light-emitting element group 12c.

Full-wave rectifying circuit 17 has output terminal 17a electrically connected to the anode terminal of first light-emitting element group 12a.

First light-emitting element group 12a has the cathode terminal electrically connected to the anode terminal of second light-emitting element group 12b and one end of first switch element 16a.

Second light-emitting element group 12b has the cathode terminal electrically connected to the anode terminal of third light-emitting element group 12c and one end of second switch element 16b.

Third light-emitting element group 12c has the cathode terminal electrically connected to one end of third switch element 16c.

Full-wave rectifying circuit 17 has output terminal 17b electrically connected to another end of first switch element 16a and another end of second switch element 16b.

### [Operation by Light-Emitting Device]

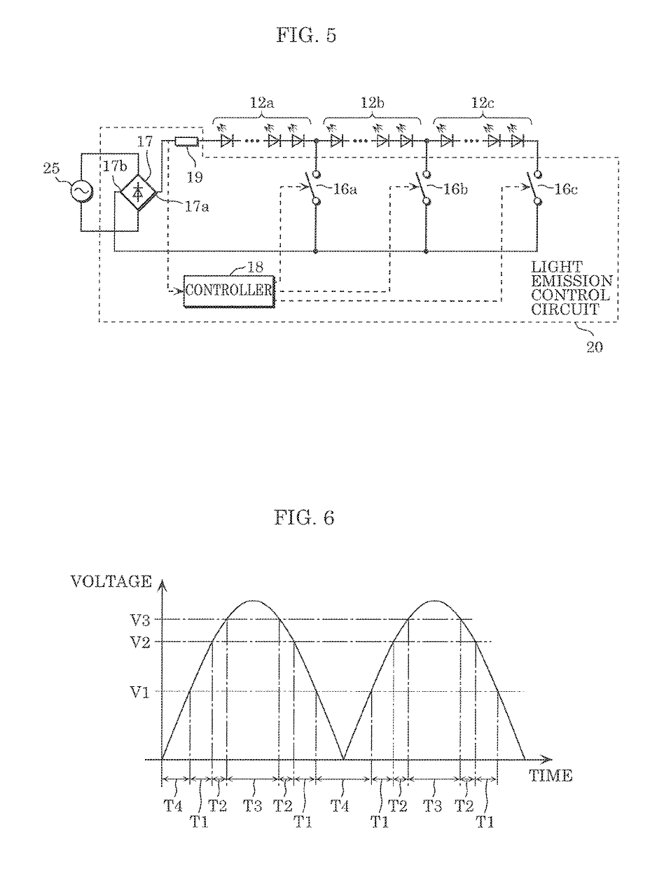

Next, operations performed by light-emitting device 10 will be described. FIG. 6 is a graph illustrating a waveform of undulating voltage to describe operations performed by light-emitting device 10.

When light-emitting device 10 is in operation, controller 18 increases the number of LED chips 12 emitting light as an instantaneous value of undulating voltage increases. Controller 18 turns on first switch element 16a, second switch element 16b, and third switch element 16c in listed order during a period in which the instantaneous value of the undulating voltage increases. Subsequently, controller 18 turns off third switch element 16c, second switch element 16b, and first switch element 16a in listed order during a period in which the instantaneous value of the undulating voltage decreases. This process is repeated for every cycle of the undulating voltage (half cycle of the alternating-current voltage supplied by external power source 25).

For example, as illustrated in FIG. 6, controller 18 turns off all of first switch element 16a, second switch element 16b, and third switch element 16c during period T4. Period T4 is a period in which the undulating voltage is at least 0 and at most V1. None of first light-emitting element group 12a, second light-emitting element group 12b, and third light-emitting element group 12c emits light during period T4. Accordingly, light-emitting device 10 is turned off.

Moreover, during period T1 following period T4, controller 18 turns on, among first switch element 16a, second switch element 16b, and third switch element 16c, only first switch element 16a, and turns off second switch element 16b and third switch element 16c. Period T1 is a period in which the undulating voltage is greater than V1 and at most V2. Period T1 is one example of a first period in which undulating voltage has a magnitude less than a predetermined value. An undulating voltage of the predetermined value is a voltage (e.g., V1, V2, or V3) greater than 0V and less than maximum voltage Vmax in cycle variation of the undulating voltage. It is to be noted that the notation 0<V1<V2<V3<Vmax is shown in FIG. 6. During period T1, first light-emitting element group 12a emits light, and second light-emitting element group 12b and third light-emitting element group 12c emit no light.

Moreover, during period T2 following period T1, controller 18 turns on, among first switch element 16a, second switch element 16b, and third switch element 16c, only second switch element 16b, and turns off first switch element 16a and third switch element 16c. Period T2 is a period in which the undulating voltage is greater than V2 and at most V3. Period T2 is an example of a second period in which undulating voltage has a magnitude greater than the predetermined value. During period T2, first light-emitting element group 12a and second light-emitting element group 12b emit light, and third light-emitting element group 12c emits no light.

Moreover, during period T3 following period T2, controller 18 turns on, among first switch element 16a, second switch element 16b, and third switch element 16c, only third switch element 16c, and turns off first switch element 16a and second switch element 16b. Period T3 is a period in which the undulating voltage is greater than V3. All of first light-emitting element group 12a, second light-emitting element group 12b, and third light-emitting element group 12c emit light during period T3.

As stated above, light emission control circuit 20 increases the number of LED chips 12 emitting light, during a period in which the magnitude of the undulating voltage is greater. Such control by light emission control circuit 20 (controller 18) makes it possible to improve light emission efficiency. It is to be noted that, in light-emitting device 10, although LED chips 12 are classified into the three light-emitting element groups, LED chips 12 may be classified into at least two light-emitting element groups. Furthermore, LED chips 12 may be finely classified into at least four light-emitting element groups. This makes it possible to further improve the light emission efficiency.

Moreover, when light-emitting device 10 is in operation, first light-emitting element group 12a has the longest light emission period, second light-emitting element group 12b has the second longest light emission period, and third light-emitting element group 12c has the shortest light emission period.

### [Advantageous Effects etc.]

In light-emitting device 10 which operates by being supplied with undulating voltage, the number of LED chips 12 emitting light varies during the operation, and thus reducing a flicker is problematic. In view of this, light-emitting device 10 includes: board 11; first light-emitting element group 12a and second light-emitting element group 12b, each of first light-emitting element group 12a and second light-emitting element group 12b including at least one light-emitting element; and light emission control circuit 20 which causes first light-emitting element group 12a and second light-emitting element group 12b to emit light, by supplying undulating voltage to first light-emitting element group 12a and second light-emitting element group 12b. Light emission control circuit 20 causes, from among first light-emitting element group 12a and second light-emitting element group 12b, first light-emitting element group 12a to emit light, by supplying the undulating voltage to first light-emitting element group 12a, during period T1 in which a magnitude of the undulating voltage is greater than voltage V1 and at most voltage V2, voltage V2 being less than a maximum value of the undulating voltage. Light emission control circuit 20 causes first light-emitting element group 12a and second light-emitting element group 12b to emit light, by supplying the undulating voltage to first light-emitting element group 12a and second light-emitting element group 12b, during period T2 in which the magnitude of the undulating voltage is greater than voltage V2. Light emission control circuit 20 is an example of a light emission controller, voltage V1 is an example of a first predetermined voltage, and voltage V2 is an example of a second predetermined voltage. Second light-emitting element group 12b surrounds first light-emitting element group 12a on board 11. Period T1 is an example of the first period, and period T2 is an example of the second period.

With this, first light-emitting element group 12a whose light emission period during the operation of light-emitting device 10 is longer than the light emission period of second light-emitting element group 12b is disposed closer to the center of board 11 than second light-emitting element group 12 is. Because the light emission period of first light-emitting element group 12a which is closer to the center and is easily recognized by a user is long, light-emitting device 10 makes it possible to reduce a flicker. In other words, it is possible to make a flicker less noticeable.

Moreover, light emission control circuit 20 may be disposed on board 11.

With this, because first light-emitting element group 12a, second light-emitting element group 12b, and light emission control circuit 20 are disposed on single board 11, it is possible to downsize light-emitting device 10 further than a case where light emission control circuit 20 is disposed on another board.

Moreover, light emission control circuit 20 may include: first switch element 16a which is turned on to supply the undulating voltage to first light-emitting element group 12a; and second switch element 16b which is turned on to supply the undulating voltage to second light-emitting element group 12b.

With this, light emission control circuit 20 makes it possible to supply the undulating voltage to first light-emitting element group 12a and second light-emitting element group 12b by controlling first switch element 16a and second switch element 16b.

Moreover, light emission control circuit 20 may include full-wave rectifying circuit 17 which full-wave rectifies alternating-current voltage to generate the undulating voltage. Full-wave rectifying circuit 17 has one output terminal 17a which may be electrically connected to an anode terminal of first light-emitting element group 12a, and first light-emitting element group 12a has a cathode terminal which may be electrically connected to an anode terminal of second light-emitting element group 12b and one end of first switch element 16a. Second light-emitting element group 12b has a cathode terminal which may be electrically connected to one end of second switch element 16b, and full-wave rectifying circuit 17 has another output terminal 17b which may be electrically connected to another end of first switch element 16a and another end of second switch element 16b.

With this, light emission control circuit 20 having a configuration as illustrated in FIG. 5 makes it possible to supply the undulating voltage to first light-emitting element group 12a and second light-emitting element group 12b.

Moreover, light emission control circuit 20 may switch on, from among first switch element 16a and second switch element 16b, first switch element 16a during period T1, and switch on, from among first switch element 16a and second switch element 16b, second switch element 16b during period T2.

With this, light emission control circuit 20 makes it possible to cause first light-emitting element group 12a to emit light during period T1, and to cause first light-emitting element group 12a and second light-emitting element group 12b to emit light during period T2.

Moreover, light-emitting device 10 may further include a sealing member which collectively seals first light-emitting element group 12a and second light-emitting element group 12b.

With this, light-emitting device 10 can be realized as a light-emitting device having the COB structure. Generally, LED chips 12 are smaller than surface mount device (SMD) LED elements including LED chips 12. In consequence, light-emitting device 10 having the COB structure makes it possible to reduce a light emission region further than a light-emitting device having an SMD structure in which the SMD LED elements are disposed instead of LED chips 12. For this reason, light-emitting device 10 having the COB structure makes easy light distribution control using an optical component such as a lens.

Moreover, the number of at least one LED chip 12 included in first light-emitting element group 12a may be greater than the number of at least one LED chip 12 included in second light-emitting element group 12b.

With this, because a light emission region which has a long light emission period and is broad is formed at a portion close to the center easily recognized by the user of light-emitting device 10, it is possible to reduce a flicker.

Incidentally, the number of at least one LED chip 12 included in first light-emitting element group 12a may be less than the number of at least one LED chip 12 included in second light-emitting element group 12b.

The magnitude of the undulating voltage necessary for causing first light-emitting element group 12a to emit light gets smaller as the number of LED chips 12 included in first light-emitting element group 12a is less. Consequently, because first light-emitting element group 12a can be caused to start emitting light early, it is possible to shorten period T4 in which light-emitting device 10 is turned off. Accordingly, it is possible to reduce a flicker by shortening period T4 in which light-emitting device 10 is turned off.

### [Variations]

The electrical connection relationship among LED chips 12 in each of first light-emitting element group 12a, second light-emitting element group 12b, and third light-emitting element group 12c, which is described in Embodiment 1, is a mere example. For example, some of LED chips 12 may be connected in parallel in each of first light-emitting element group 12a, second light-emitting element group 12b, and third light-emitting element group 12c.

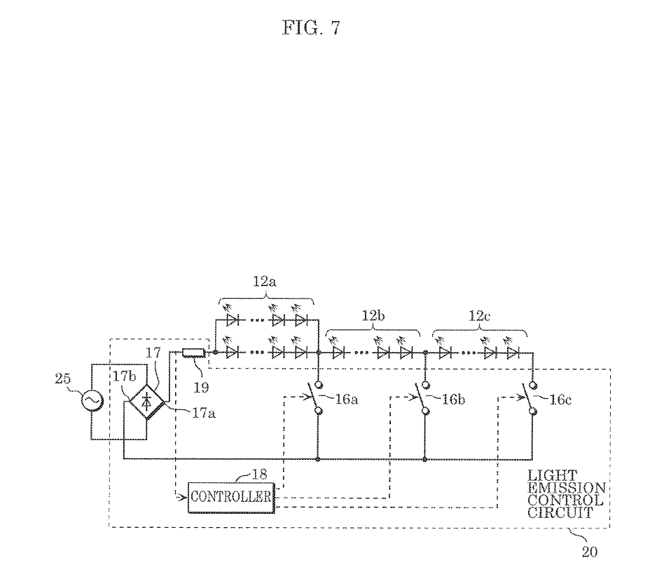

For example, as illustrated in FIG. 7, first light-emitting element group 12a may include LED chips 12 connected in parallel. Specifically, LED chips 12 included in first light-emitting element group 12a may be classified into two groups each including LED chips 12 connected in series, and the two groups may be connected in parallel. FIG. 7 is a diagram illustrating an electrical connection relationship among LED chips 12 according to a variation.

Such a configuration makes it possible to cause many LED chips 12 to emit light with a relatively low undulating voltage, and is thus useful when it is desired that the number of LED chips 12 included in first light-emitting element group 12a be greater than those of second light-emitting element group 12b and third light-emitting element group 12c.

Moreover, a current flowing through one LED chip 12 is reduced by connecting in parallel some of LED chips 12 included in first light-emitting element group 12a, and thus it is possible to curb the rise in temperature of LED chips 12. As a result, it is possible to improve the light emission efficiency of first light-emitting element group 12a (light-emitting device 10).

### Embodiment 2

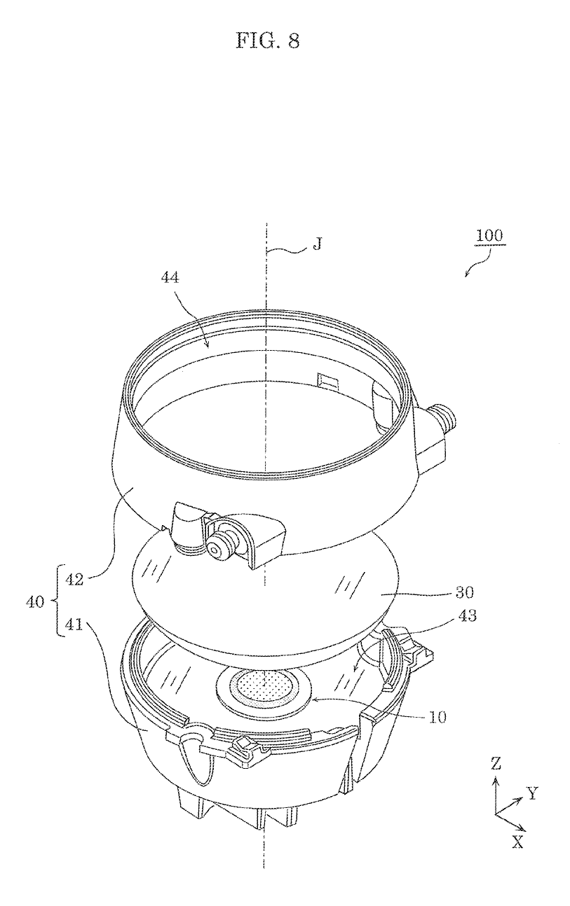

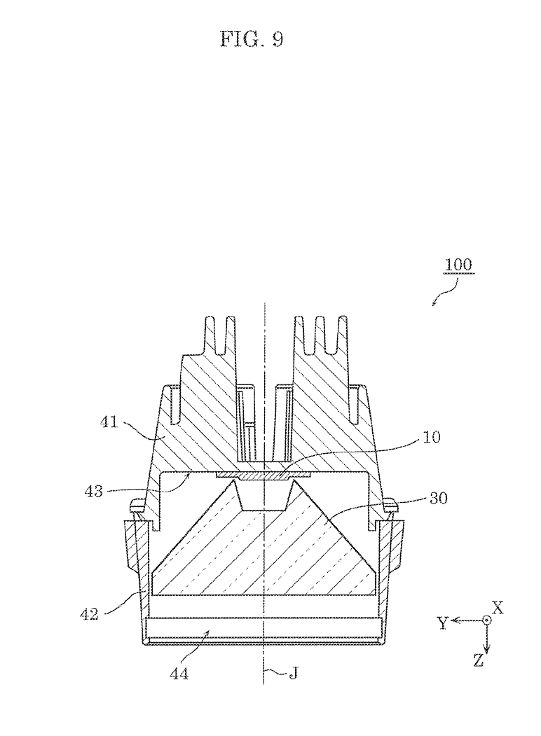

An illuminating apparatus including light-emitting device 10 will be described in Embodiment 2. FIG. 8 is an exploded perspective view illustrating the illuminating apparatus according to Embodiment 2. FIG. 9 is a schematic cross-sectional view illustrating the illuminating apparatus according to Embodiment 2.

Illuminating apparatus 100 illustrated in FIG. 8 and FIG. 9 is an illuminating apparatus used as, for example, a spotlight or a downlight. Illuminating apparatus 100 includes light-emitting device 10, lens 30, and housing 40 (first housing 41 and second housing 42).

It is to be noted that FIG. 8 and FIG. 9 also show lamp axis J (hereinafter simply referred to as axis J) of illuminating apparatus 100. Axis J is the central axis of illuminating apparatus 100 and coincides with the optical axis of light-emitting device 10 and the optical axis of lens 30.

Moreover, in Embodiment 2, a Z-axis direction is, for example, the vertical direction, and a positive Z-axis side is referred to as a light emission side. In addition, a negative Z-axis side is referred to as an installation surface side. Furthermore, an X-axis direction and a Y-axis direction are orthogonal to each other on a plane (a horizontal plane) perpendicular to the Z-axis direction. The following describes structural elements other than light-emitting device 10 included in illuminating apparatus 100. A description of light-emitting device 10 overlaps the one in Embodiment 1 and is omitted accordingly.

Lens 30 is an optical member for giving a predetermined (designed) light distribution property to illuminating apparatus 100, and is disposed opposite the light emission side of illuminating apparatus 10. Specifically, lens 30 is disposed such that an entrance surface of lens 30 is opposite light-emitting device 10, and collects light incident on the entrance surface and emits the light from an exit surface of lens 30. Lens 30 is disposed such that the optical axis of lens 30 coincides with the optical axis of light emitter 22. The plan view shape (shape viewed from the direction of axis J) of lens 30 is a round shape whose diameter is greater than that of light-emitting device 10. When viewed from the direction of axis J, light-emitting device 10 is covered with lens 30.

Lens 30 is secured to second housing 42 to block from inside light exit opening 44 (a main opening) formed in second housing 41. Lens 30 is made of, for example, a transparent resin material (a translucent resin material) such as PMMA (acryl) and polycarbonate, but may be made of a transparent material such as a glass material.

Housing 40 houses light-emitting device 10 and lens 30, and includes first housing 41 and second housing 42.

First housing 41 is a portion of housing 40 which is on the installation surface side and serves as a mounting base on which light-emitting device 10 is mounted. First housing 41 has a substantially truncated cone shape whose diameter gradually increases from the installation surface side toward the light emission side. First housing 41 has mounting surface 43 with which the back surface (a surface on which LED chips 12 are not mounted) of light-emitting device 10 makes surface contact.

Moreover, first housing 41 serves as a heat sink which dissipates heat generated by light-emitting device 10. First housing 41 is made of, for example, a metal material such as an aluminum die-cast metal, but may be made of another material. It is to be noted that a heat dissipation member (a thermal sheet, thermal grease, or the like) may be disposed between mounting surface 43 and light-emitting device 10.

Second housing 42 is a portion of housing 40 on the light emission side, and light emission opening 44 is formed in second housing 42. Second housing 42 has a substantially cylindrical shape whose inner diameter gradually decreases from the installation surface side toward the light emission side. Second housing 42 is made of, for example, a metal material such as an aluminum die-cast metal, but may be made of another material.

It is to be noted that although not shown, a wire taken out from external power source 25 is electrically connected to light-emitting device 10 housed in housing 40. This wire is inserted into, for example, housing 40 via an opening formed in second housing 42.

### [Advantageous Effects etc. of Embodiment 2]

As described above, illuminating apparatus 100 includes light-emitting device 10 and lens 30 disposed opposite light-emitting device 10.

When lens 30 is disposed opposite light-emitting device 10 as above, the center of a light emission region (a region in which sealing member 13 is disposed) of light-emitting device 10 is often used as a reference in optical design for lens 30 and the like. In this case, the influence of light at the center of light-emitting device 10 grows on an irradiated surface to which illuminating apparatus 100 emits light.

Here, as stated above, in light-emitting device 10, first light-emitting element group 12a whose light emission period is longer than the light emission period of second light-emitting element group 12b is disposed closer to the center of the light emission region (the center of board 11) than second light-emitting element group 12b is. With this, first light-emitting element group 12a having a long emission period is disposed at a position close to the center of the light emission region in which the influence on the irradiated surface grows, and second light-emitting element group 12b and third light-emitting element group 12c whose light emission period is shorter than the light emission period of first light-emitting element group 12a are disposed close to the periphery of the light emission region in which the influence on the irradiated surface diminishes. As a result, a flicker is reduced.

It is to be noted that although illuminating apparatus 100 has been described as a downlight or a spotlight, illuminating apparatus 100 may be another illuminating apparatus such as a road light. In other words, an illuminating apparatus including light-emitting device 10 is not particularly limited.

### Other Embodiments

Although the light-emitting device and illuminating apparatus according to the aforementioned embodiments have been described above, the present disclosure is not limited to the aforementioned embodiments.

For example, the circuit configuration of the light emission control circuit described in the aforementioned embodiments is a mere example. The present disclosure also includes a light emission control circuit capable of performing the characteristic functions of the present disclosure, like the above circuit configuration. The light emission control circuit may include, for example, a switch element disposed between light-emitting element groups connected in series.

Moreover, for example, the present disclosure also includes a circuit configuration in which elements such as a switching element (transistor), a resistance element, and a capacitative element are connected in series or parallel with an element to the extent that the circuit configuration enables functions similar to those of the above circuit configuration. Specifically, the “connection” in the aforementioned embodiments is not limited to direct connection of two terminals (nodes) but includes connection of the two terminals (nodes) via an element to the extent that the connection achieves a circuit configuration enabling the similar functions.

Moreover, although the light-emitting region (region in which the sealing member is placed) of the light-emitting device has the round shape in the aforementioned embodiments, the light-emitting region may have a rectangular shape. In addition, the second light-emitting element group and the third light-emitting element group may be disposed in a rectangular annular shape.

Moreover, although the light-emitting device having the COB structure has been described in the aforementioned embodiments, the present disclosure can also be applied to a light-emitting device having the SMD structure. The light-emitting device having the SMD structure includes, for example, as a light-emitting element, an SMD light-emitting element including a resin container having a concave portion, an LED chip mounted inside the concave portion, and a sealing member (phosphor-containing resin) filling the inside of the concave portion.

Moreover, although the light-emitting device emits white light using a combination of the LED chips which emit blue light and the yellow phosphor in the aforementioned embodiments, the configuration for emitting white light is not limited to this. For example, a phosphor-containing resin including a red phosphor and a green phosphor may be combined with an LED chip which emits blue light. Alternatively, an LED chip which emits purple light or ultraviolet light having a wavelength shorter than that of blue light emitted by the LED chip may be combined with a blue phosphor, a green phosphor, and a red phosphor which emit blue light, red light, and green light, respectively, as a result of being excited by purple light or ultraviolet light. In other words, the LED chip may emit purple light or ultraviolet light.

Moreover, the light-emitting elements included in the light-emitting device are exemplified as the LED chips in the aforementioned embodiments. However, semiconductor light-emitting elements such as semiconductor lasers or solid-state light-emitting elements such as organic electroluminescent (EL) elements or inorganic EL elements may be used as the light-emitting elements.

Moreover, light-emitting elements of two or more types different in light-emission color may be included in the light-emitting device. For example, the light-emitting device may include LED chips which emit red light in addition to LED chips which emit blue light or purple light, for the purpose of increasing a color rendering property or the like.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A light-emitting device, comprising:
a board;
a first light-emitting element group and a second light-emitting element group which are disposed on the board, each of the first light-emitting element group and the second light-emitting element group including at least one light-emitting element; and
a light emission controller which causes the first light-emitting element group and the second light-emitting element group to emit light, by supplying undulating voltage to the first light-emitting element group and the second light-emitting element group,
wherein the light emission controller is configured to:
cause, from among the first light-emitting element group and the second light-emitting element group, the first light-emitting element group to emit light, by supplying the undulating voltage to the first light-emitting element group, during a first period in which a magnitude of the undulating voltage is greater than a first predetermined value and at most a second predetermined value, the second predetermined value being less than a maximum value of the undulating voltage; and
cause the first light-emitting element group and the second light-emitting element group to emit light, by supplying the undulating voltage to the first light-emitting element group and the second light-emitting element group, during a second period in which the magnitude of the undulating voltage is greater than the second predetermined value, and
the second light-emitting element group surrounds the first light-emitting element group on the board.

2. The light-emitting device according to claim 1,
wherein the light emission controller is disposed on the board.

3. The light-emitting device according to claim 2,
wherein the light emission controller includes:
a first switch which is configured to be switched on to supply the undulating voltage to the first light-emitting element group; and
a second switch which is configured to be switched on to supply the undulating voltage to the second light-emitting element group.

4. The light-emitting device according to claim 3,
wherein the light emission controller further includes a full-wave rectifying circuit which full-wave rectifies alternating-current voltage to generate the undulating voltage,
the full-wave rectifying circuit includes one output terminal electrically connected to an anode terminal of the first light-emitting element group,
the first light-emitting element group includes a cathode terminal electrically connected to an anode terminal of the second light-emitting element group and one end of the first switch,
the second light-emitting element group includes a cathode terminal electrically connected to one end of the second switch, and
the full-wave rectifying circuit includes another output terminal electrically connected to another end of the first switch and another end of the second switch.

5. The light-emitting device according to claim 4,
wherein each of the first light-emitting element group and the second light-emitting element group includes a plurality of light-emitting elements,
the plurality of light-emitting elements included in the first light-emitting element group are connected in series,
the plurality of light-emitting elements included in the second light-emitting element group are connected in series, and
the first light-emitting element group and the second light-emitting element group are connected in series.

6. The light-emitting device according to claim 4,
wherein at least one of the first light-emitting element group and the second light-emitting element group includes a plurality of light-emitting elements,
a first portion of the plurality of light-emitting elements included in the at least one of the first light-emitting element group and the second light-emitting element group is connected in series, and
a second portion of the plurality of light-emitting elements included in the at least one of the first light-emitting element group and the second light-emitting element group is connected in parallel.

7. The light-emitting device according to claim 3,
wherein the light emission controller switches on, from among the first switch and the second switch, the first switch during the first period, and switches on, from among the first switch and the second switch, the second switch during the second period.

8. The light-emitting device according to claim 7,
wherein the light emission controller is one of an integrated circuit, a processor, a microcomputer, and a dedicated communication circuit.

9. The light-emitting device according to claim 1, further comprising
a sealing member which collectively seals the first light-emitting element group and the second light-emitting element group.

10. The light-emitting device according to claim 9,
wherein the sealing member includes phosphor,
the phosphor is configured to convert a wavelength of a portion of the light emitted by the first light-emitting element group and the second light-emitting element group, and
the sealing member is configured to diffuse and mix the portion of the light having the converted wavelength and a portion of the light emitted by the first light-emitting element group and the second light-emitting element group which is not absorbed by the phosphor.

11. The light-emitting device according to claim 1,
wherein a number of the at least one light-emitting element included in the first light-emitting element group is greater than a number of the at least one light-emitting element included in the second light-emitting element group.

12. The light-emitting device according to claim 1,
wherein a number of the at least one light-emitting element included in the first light-emitting element group is less than a number of the at least one light-emitting element included in the second light-emitting element group.

13. The light-emitting device according to claim 1,
wherein the second light-emitting element group is disposed on the board to annularly surround the first light-emitting element group.

14. The light-emitting device according to claim 1,
wherein the light emission controller is configured to increase a number of light-emitting elements emitting light in accordance with an instantaneous value of the undulating voltage increasing.

15. The light-emitting device according to claim 1, further comprising
a third light-emitting element group disposed on the board, the third light-emitting element group including at least one light-emitting element,
wherein the light emission controller is configured to:
cause, from among the first light-emitting element group, the second light-emitting element group, and the third light-emitting element group, the first light-emitting element group to emit light, by supplying the undulating voltage to the first light-emitting element group, during the first period;
cause, from among the first light-emitting element group, the second light-emitting element group, and the third light-emitting element group, the first light-emitting element group and the second light-emitting element group to emit light during the second period in which the magnitude of the undulating voltage is greater than the second predetermined value and at most a third predetermined value, the third predetermined value being less than the maximum value of the undulating voltage; and
cause the first light-emitting element group, the second light-emitting element group, and the third light-emitting element group to emit light, by supplying the undulating voltage to the first light-emitting element group, the second light-emitting element group, and the third light-emitting element group, during a third period in which the magnitude of the undulating voltage is greater than the third predetermined value.

16. The light-emitting device according to claim 15,
wherein a number of the at least one light-emitting element included in the first light-emitting element group is greater than both a number of the at least one light-emitting element included in the second light-emitting element group and a number of the at least one light-emitting element included in the third light-emitting element group, and
the number of the at least one light-emitting element included in the second light-emitting element group is greater than the number of the at least one light-emitting element included in the third light-emitting element group.

17. The light-emitting device according to claim 16,
wherein the second light-emitting element group is disposed on the board to surround a periphery of the first light-emitting element group,
the third light-emitting element group is disposed on the board to surround a periphery of the second light-emitting element group, and
the third light-emitting element group is disposed on the board circularly in a concentric fashion with the second light-emitting element group.

18. An illuminating apparatus, comprising:
the light-emitting device according to claim 1; and
a lens disposed opposite the light-emitting device.

19. An illuminating apparatus, comprising:
a light-emitting device;
a housing defining an opening for emitting light; and
a lens disposed between the light-emitting device and the opening of the housing,
wherein the light-emitting device includes:
a board;
a first light-emitting element group and a second light-emitting element group which are disposed on the board, each of the first light-emitting element group and the second light-emitting element group including at least one light-emitting element; and
a light emission controller which causes the first light-emitting element group and the second light-emitting element group to emit light, by supplying undulating voltage to the first light-emitting element group and the second light-emitting element group,
the light emission controller is configured to:
cause, from among the first light-emitting element group and the second light-emitting element group, the first light-emitting element group to emit light, by supplying the undulating voltage to the first light-emitting element group, during a first period in which a magnitude of the undulating voltage is greater than a first predetermined value and at most a second predetermined value, the second predetermined value being less than a maximum value of the undulating voltage; and
cause the first light-emitting element group and the second light-emitting element group to emit light, by supplying the undulating voltage to the first light-emitting element group and the second light-emitting element group, during a second period in which the magnitude of the undulating voltage is greater than the second predetermined value,
the second light-emitting element group surrounds the first light-emitting element group on the board,
the lens is an optical member having a predetermined light distribution property,
a central axis of the housing coincides with an optical axis of the light-emitting device and an optical axis of the lens, and
a diameter of the lens along the central axis of the housing is greater than a diameter of the light-emitting device along the central axis.

20. A method of operating a light-emitting device, the light-emitting device including a first light-emitting element group and a second light-emitting element group disposed on a board, the second light-emitting element group surrounding the first light-emitting element group on the board, the method comprising
supplying, by a light emission controller, undulating voltage to at least one light-emitting element of the first light-emitting element group and at least one light-emitting element of the second light-emitting element group to cause the first light-emitting element group and the second light-emitting element group to emit light,
wherein, in the supplying:
the undulating voltage is supplied to the first light-emitting element group to cause the first light-emitting element group to emit light, from among the first light-emitting element group and the second light-emitting element group, during a first period in which a magnitude of the undulating voltage is greater than a first predetermined value and at most a second predetermined value, the second predetermined value being less than a maximum value of the undulating voltage; and
the undulating voltage is supplied to the first light-emitting element group and the second light-emitting element group to cause the first light-emitting element group and the second light-emitting element group to emit light during a second period in which the magnitude of the undulating voltage is greater than the second predetermined value.
